(19) United States
(12) Patent Application Publication
(10) Pub. No.: US 2012/0086117 A1
(43) Pub. Date: Apr. 12, 2012

(54) PACKAGE WITH EMBEDDED CHIP AND METHOD OF FABRICATING THE SAME

(75) Inventors: Chiang-Cheng Chang, Taichung (TW); Hsin-Yi Liao, Taichung (TW); Shih-Kuang Chiu, Taichung (TW)

(73) Assignee: SILICONWARE PRECISION INDUSTRIES CO., LTD., Taichung (TW)

(21) Appl. No.: 12/965,215

(22) Filed: Dec. 10, 2010

(30) Foreign Application Priority Data
Oct. 6, 2010 (TW) 099133962

(51) Int. Cl. H01L 23/36; H01L 21/60

(52) U.S. Cl. 257/706; 438/122; 257/E23.101; 257/E21.506

(57) ABSTRACT

A package embedded with a chip and a method of fabricating the package of embedded chip. The package of embedded chip includes a dielectric layer having a first surface and a second surface opposing the first surface; a plurality of conductive pillars formed in the dielectric layer and exposed from the second surface of the dielectric layer; a chip embedded in the dielectric layer; a circuit layer formed on the first surface of the dielectric layer; a plurality of conductive blind vias formed in the dielectric layer, allowing the circuit layer to be electrically connected via the conductive blind vias to the chip and each of the conductive pillars; and a first solder mask layer formed on the first surface of the dielectric layer and the circuit layer, thereby using conductive pillars to externally connect with other electronic devices as required to form a stacked structure. Therefore, the manufacturing process can be effectively simplified.

### BACKGROUND OF THE INVENTION

1. Field of the Invention

This invention relates to packages and methods of fabricating the same, and more particularly, to a package with an embedded chip and a method of fabricating the same.

2. Description of Related Art

With the advancement of semiconductor technology, a semiconductor product may be in various package forms. In order to pursue the goal of compact size, a chip scale package (CSP) is brought to the market that is characterized in that the chip scale package is the same as or slightly greater than a chip in size.

U.S. Pat. Nos. 5,892,179, 6,103,552, 6,287,893, 6,350,668 and 6,433,427 disclosed a conventional CSP structure in which a built-up structure is formed on a chip directly, without using a chip carrier, such as a substrate or a lead frame. A redistribution layer (RDL) technique is used to redistribute electrode pads on the chip to desired locations.

However, the above CSP structure has an disadvantage that the application of the RDL technique and the conductive traces applied on the chip are limited by the size of the chip or the area of an active surface of the chip. In consequence, as the chip is higher in integration and smaller in size, there is no sufficient area on the chip for a greater number of solder balls to be implanted on the chip for the chip to be electrically connected to external electronic devices.

To address the disadvantage, U.S. Pat. No. 6,271,469 discloses a method of fabricating a wafer-level chip scale package (WLCSP), including forming a built-up package on a chip, so as to provide a spacious enough surface area on which a greater number of input/output ends or solder balls may be installed.

As shown in FIG. 1A, a glue film 11 is provided for a plurality of chips 12 to be adhered to the glue film 11 with an active surface 121 of each of the chips 12 being attached to the glue film 11. The glue film 11 is, for example, a thermally sensitive glue film. As shown in FIG. 1B, a package molding process is performed, to form an encapsulant 13 such as epoxy resin, for encapsulating an inactive surface 122 and lateral surfaces of the chip 12, and then the glue film 11 is thermally removed for exposing the active surface 121 of the chip 12. As shown in FIG. 1C, the RDL technique is employed to apply a dielectric layer 14 on the active surface 121 of the chip 12 and the encapsulant 13. A plurality of openings are then formed that penetrate the dielectric layer 14 to expose the electrode pads 120 on the chip 12, a circuit layer 15 is formed on the dielectric layer 14 for electrically connecting the circuit layer 15 to the electrode pads 120. A solder mask layer 16 is formed on the circuit layer 15 and solder balls 17 are implanted on predetermined positions of the circuit layer 15. And finally a singulation process is performed.

Through the above processes, more solder balls 17 may be formed to be connected with other electronic devices, because the encapsulant 13 that encapsulates the chip 12 may provide a surface area greater than the active surface 121 of the chip 12.

However, the drawbacks of the above processes include that since the chip 12 is adhered to the glue film 11 with the active surface 121 facing the glue film 11, the glue film 11 is likely extended or contracted due to the heating to the glue film 11, and, as such, the chip 12 is offset, and that the softened glue film 11 due to the heat during the package mold process makes the chip 12 offset. Further, the circuit layer 15 cannot be connected to the electrode pads 120 of the chip 12 during the subsequent RDL process, which results in poor electrical connection quality.

Please refer to FIG. 2. In another package mold, because the glue film 11′, when heated, is easily softened, an excessive glue 130 is likely flashed on the active surface 121 of the chip 12, or even contaminates the electrode pads 120. As a result, the circuit layer is in poor contact with the electrode pads of the chip 12 during the subsequent RDL process, and thus the package is invalid.

Referring to FIG. 3A, during the above package molding process, only the glue film 11 is used to support the plurality of chips 12. Therefore, the glue film 11 and the encapsulant 13 suffer server warpage 110 problems, especially when the encapsulant 13 is very thin. Accordingly, the dielectric layer 14 that is applied on the chip 12 during the subsequent RDL process may have uneven thickness. A hard carrier 18 is thus required additionally, as shown in FIG. 3B, and the encapsulant 13 may be fixed to the hard carrier 18 with a glue 19 and be flattened. After the RDL process is completed and the carrier 18 is removed, a glue 190 is likely remained on the encapsulant 13, as shown in FIG. 3C. Other related techniques are disclosed in U.S. Pat. Nos. 6,498,387, 6,586,822, 7,019,406 and 7,238,602.

As shown in FIG. 3D, a stacking process cannot be performed unless the encapsulant 13 has been drilled, a through mold via (TMV) process has been performed to the encapsulant 13 to form a plurality of vias, the vias have been filled with a conductive material 100 by electroplating or electroless plating processes to form a plurality of conductive vias 10, and solder balls 17′ have been formed on the conductive vias 10 for an electronic device 1 of another package to be mounted thereon. However, penetrating the encapsulant 13 is complicated, and the conductive material 100 needs to be filled in the vias when forming the conductive vias 10, which increases the fabrication time and cost.

Therefore, how to provide a chip scale package and a method of fabricating the same, to overcome the drawbacks of the prior art, ensure the electrical connection quality between the circuit layer and the electrode pads, improve the reliability of the product, and reduce the fabrication cost, is becoming one of the most important issues in the art.

### SUMMARY OF THE INVENTION

The present invention provides a package of embedded chip, which comprises: a dielectric layer having a first surface and a second surface opposing the first surface; a plurality of conductive pillars formed in the dielectric layer and exposed from the second surface of the dielectric layer; a chip embedded in the dielectric layer and having an active surface and an inactive surface opposing the active surface, a plurality of electrode pads disposed on the active surface; a circuit layer formed on the first surface of the dielectric layer; a plurality of conductive blind vias formed in the dielectric layer, allowing the circuit layer to be electrically connected via the conductive blind vias to each of the electrode pads and each of the conductive pillars; and a first solder mask layer formed on the first surface of the dielectric layer and the circuit layer and having a plurality of first holes for exposing a part of the circuit layer from the first holes.

In an embodiment of the present invention, the conductive pillars are made of copper.

In an embodiment, the inactive surface of the chip is exposed from the second surface of the dielectric layer. The package further comprises a second solder mask layer that is formed on the second surface of the dielectric layer, the inactive surface of the chip and each of the conductive pillars, wherein the second solder mask layer has a plurality of second holes, allowing a part of the surfaces of each of the conductive pillars to be exposed form the second holes.

In another embodiment, the inactive surface of the chip has a heat sink. The package further comprises a second solder mask layer formed on the second surface of the dielectric layer, the heat sink and each of the conductive pillars, wherein the second solder mask layer has a plurality of second holes, allowing a part of each of the conductive pillars to be exposed form the second holes.

The package further comprises a plurality conductive elements formed on the circuit layer in each of the first holes.

The package further comprises a built-up structure that is formed on the first surface of the dielectric layer and the circuit layer, wherein the first solder mask layer is formed on an outermost layer of the built-up structure.

The present invention further provides a method of fabricating a package of embedded chip, comprising: forming a plurality of neighboring conductive pillars on a carrier, and defining a chip-mounted region on the carrier; mounting within the chip-mounted region a chip having an active surface and an inactive surface opposing the active surface, with the inactive surface facing the carrier, wherein a plurality of the electrode pads are disposed on the active surface; forming on the carrier, each of the conductive pillars and the chip a dielectric layer to encapsulate the chip, the dielectric layer having an exposed first surface and a second surface attached to the carrier; forming a circuit layer on the first surface of the dielectric layer, and forming a plurality of conductive blind vias in the dielectric layer, allowing the circuit layer to be electrically connected via the conductive blind vias to each of the electrode pads and each of the conductive pillars; forming on the first surface of the dielectric layer and the circuit layer a first solder mask layer; removing the carrier to expose the second surface of the dielectric layer and each of the conductive pillars; and forming on the first solder mask layer a plurality of first holes for exposing a part of the circuit layer from the first holes.

In an embodiment of the present invention, the carrier and the conductive pillars are made of copper, wherein the carrier is removed by etching.

In an embodiment of the present invention, further comprises coating the inactive surface of the chip with an adhesive layer, to allow the chip to be positioned on the carrier, and removing the adhesive layer after the carrier is removed, so as to expose the inactive surface of the chip.

In an embodiment of the present invention, the inactive surface of the chip is exposed from the second surface of the dielectric after removing all of the carrier. The method further comprises forming a second solder mask layer on the second surface of the dielectric layer, the inactive surface of the chip and each of the conductive pillars, wherein the second solder mask layer has a plurality of second holes, allowing a part of each of the conductive pillars to be exposed from the second holes.

In an embodiment of the present invention, a part of the carrier is removed, allowing the residual carrier on the inactive surface of the chip to act as the heat sink. The method further comprises forming on the second surface of the dielectric layer, the heat sink and each of the conductive pillars a second solder mask layer, wherein the second solder mask layer has a plurality of second holes, allowing a part of each of the conductive pillars to be exposed from the second holes.

The method further comprises forming on the circuit layer in each of the first holes a plurality of conductive elements.

In sum, in the package of embedded chip and the method of fabricating the same of the present invention, the chip is mounted on the carrier that is formed with conductive pillars, the dielectric layer covers the chip and the conductive pillars, and then the carrier is removed, for the RDL process to be performed subsequently, so as to prevent the chip from being adhered directly to the glue film that is easily to be softened when heated, prevent the encapsulant to generate excessive glue and contaminate and offset the chip, ensure that the circuit layer is in well contact with the electrode pads during the subsequent fabrication processes, and the problem of invalid packages can be effectively avoid.

Moreover, the conductive pillars may increase the supporting force, and the problems of the prior art that the warpage happens because only the glue film is used to provide the supporting force and glue is residual on the encapsulant are solved.

Further, through the design of the conductive pillars, other electronic devices may be connected externally when the stacking process is performed, without penetrating the encapsulant to form the conductive vias, as the prior art teaches. Therefore, the fabrication process of the present invention is simplified, and the fabrication time and cost are reduced because no need of filling with the conductive material.

### BRIEF DESCRIPTION OF DRAWINGS

The invention can be more fully understood by reading the following detailed description of the preferred embodiments, with reference made to the accompanying drawings, wherein:

FIGS. 1A-1C illustrate a method of fabricating a wafer-level chip scale package disclosed in U.S. Pat. No. 6,271,469;

FIG. 2 illustrates a wafer-level chip scale package disclosed in U.S. Pat. No. 6,271,469 that suffers an excessive glue problem;

FIGS. 3A-3D illustrate a wafer-level chip scale package disclosed in U.S. Pat. No. 6,271,469 that suffers the problems of encapsulant warpage, additionally installed carrier, residual glue on the encapsulant surface, and difficult to stack; and

FIGS. 4A-4I illustrate a package of embedded chip and a method of fabricating the package of embedded chip according to the present invention, wherein FIG. 4F′ is another embodiment of FIG. 4F, FIG. 4G′ is another embodiment of FIG. 4 G, and FIG. 4I′ is another embodiment of FIG. 4I.

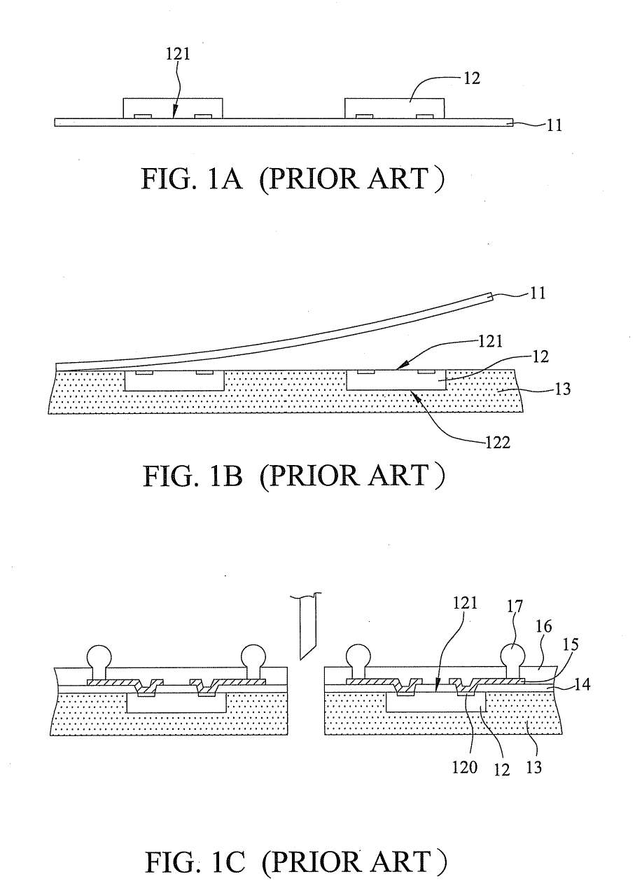

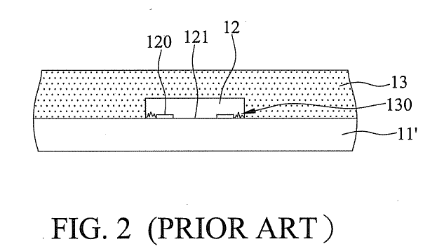

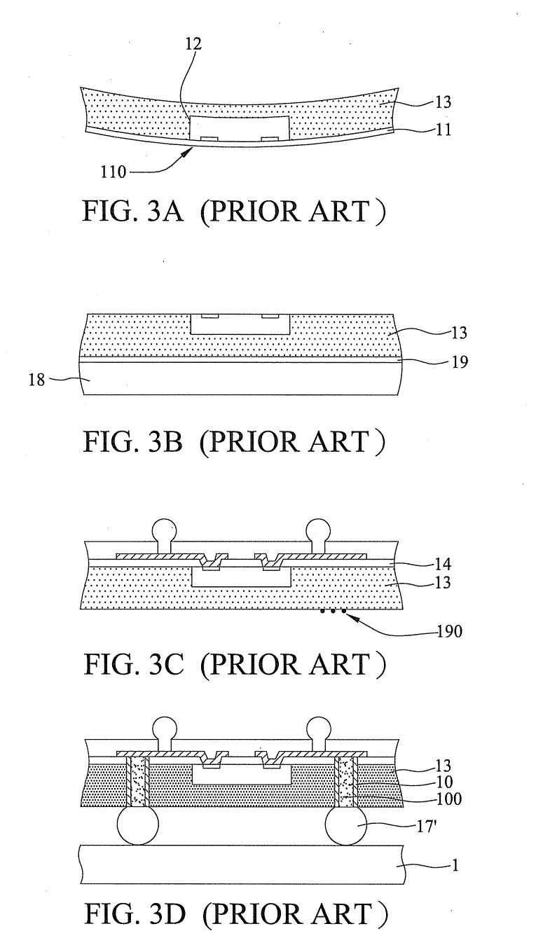

### DETAILED DESCRIPTION OF PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

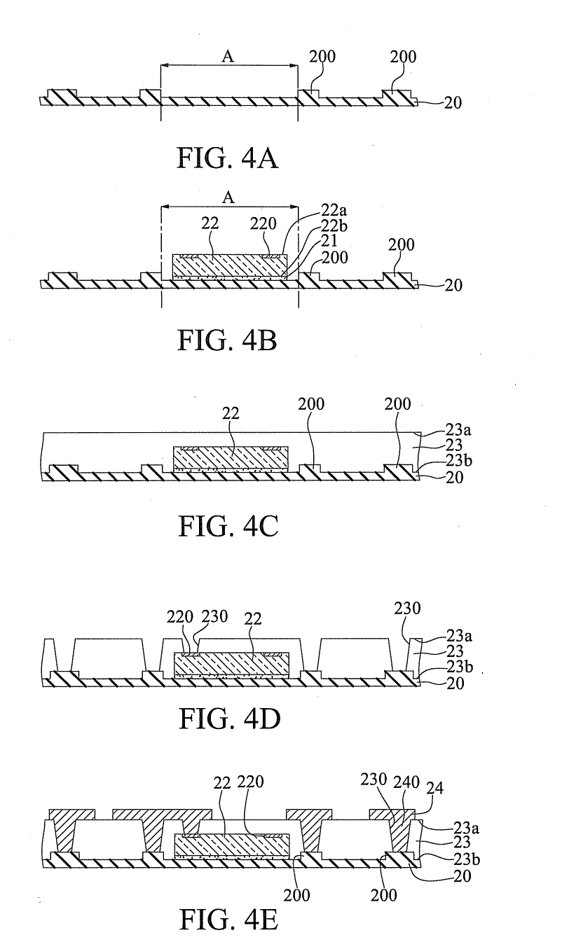

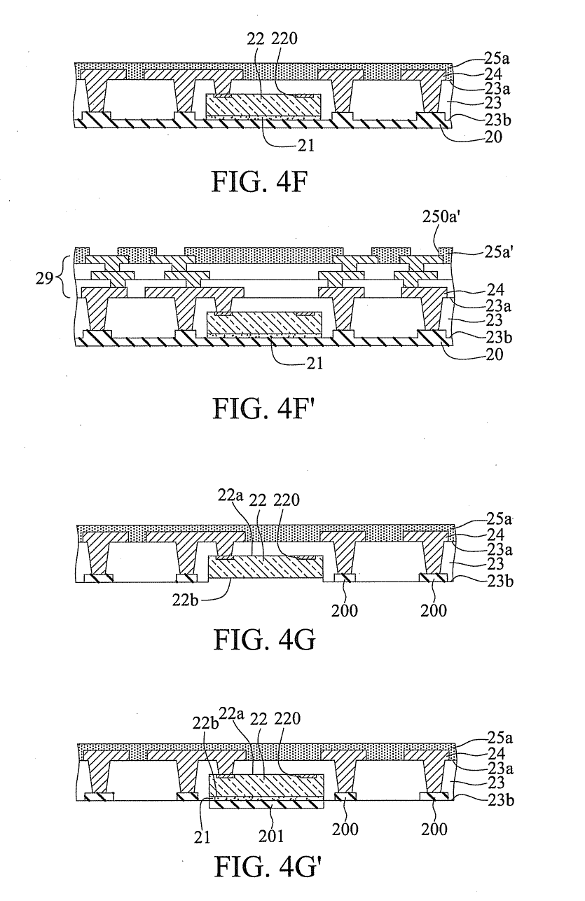

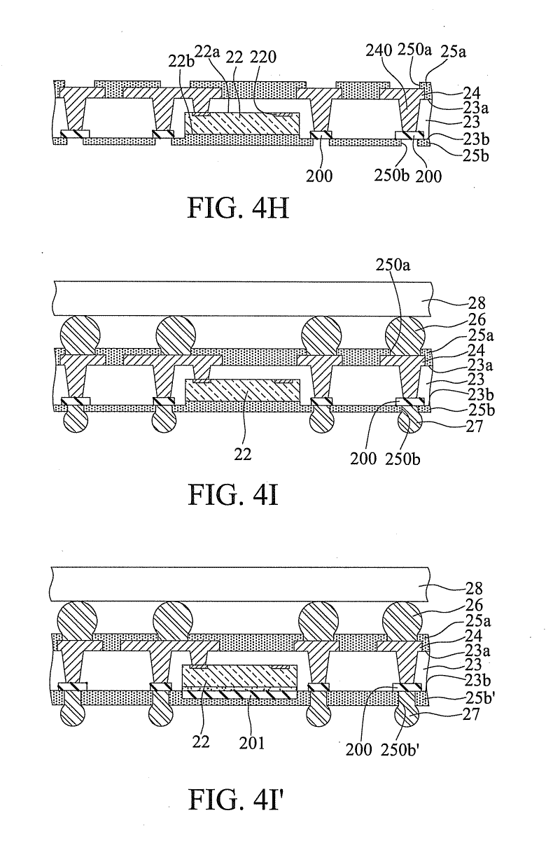

Please refer to FIGS. 4A to 4I, which illustrate a method of fabricating a package of embedded chip.

As shown in FIG. 4A, a plurality of neighboring conductive pillars 200 are formed on a carrier 20, and a chip-mounted region A is defined on the carrier 20, wherein the carrier 20 and the conductive pillars 200 are made of copper. In the embodiment, the conductive pillars 200 are formed with the carrier 20, but can be a plurality of convex portions additionally formed on the carrier 20. However, it is only exemplary and is not limited thereto.

As shown in FIG. 4B, a chip 22 is mounted on the chip-mounted region A of the carrier 20. The chip 22 has an active surface 22a and an inactive surface 22b opposing the active surface 22a. A plurality of electrode pads 220 are disposed on the active surface 22a. The chip 22 is mounted on the carrier 20 with the inactive surface 22b facing the carrier 20. In the embodiment, an adhesive layer 21 is coated on the inactive surface 22b, such that the chip 22 can be positioned to the carrier 20.

As shown in FIG. 4C, a dielectric layer 23 is formed on the carrier 20, each of the conductive pillars 200 and the chip 22, to encapsulate the chip 22. The dielectric layer 23 has an exposed first surface 23a and a second surface 23b that is combined with the carrier 20.

As shown in FIG. 4D, a plurality of blind vias 230 are formed on the first surface 23a of the dielectric layer 23, so as to expose the electrode pads 220 and each of the conductive pillars 200.

As shown in FIG. 4E, a patterned electroplating process is then performed, so as to form a plurality of conductive blind vias 240 in the blind vias 230, and form a circuit layer 24 on the conductive blind vias 240 and on the first surface 23a of the dielectric layer 23, allowing the circuit layer 24 to be electrically connected via the conductive blind vias 240 to each of the electrode pads 220 and each of the conductive pillars 200.

As shown in FIG. 4F, a first solder mask layer 25a is formed on the first surface 23a of the dielectric layer 23 and the circuit layer 24.

As shown in FIG. 4G, all of the carrier 20 is removed by etching, such that the second surface 23b of the dielectric layer 23, the adhesive layer 21 and each of the conductive pillars 200 are exposed. Then, the adhesive layer 21 is removed by a chemical agent, so as to expose the inactive surface 22b of the chip 22.

In another embodiment, as shown in FIG. 4G′, a part of the carrier 20 is removed by etching, allowing the residual carrier 20 on the inactive surface 22b of the chip 22 to act as a heat sink 201, and allowing the second surface 23b of the dielectric layer 23 and each of the conductive pillars 200 to be exposed from the heat sink 201.

Continuing the process of FIG. 4G, as shown in FIG. 4H, a plurality of first holes 250a are formed in the first solder mask layer 25a, allowing a part of the surfaces of the circuit layer 24 to be exposed form each of the first holes 250a. Further, a second solder mask layer 25b is formed on the second surface 23b of the dielectric layer 23, the inactive surface 22b of the chip 22 and each of the conductive pillars 200, and then a plurality of second holes 250b are formed in the second solder mask layer 25b, allowing a part of the surfaces of each of the conductive pillars 200 to be exposed form the second holes 250b.

As shown in FIG. 4I, in the subsequent process a plurality of conductive elements 26 such as solder balls or solder pins may be formed on the circuit layer 24 in each of the first holes 250a, in order to connect other electronic devices 28, such as a circuit board, a semiconductor chip or another package, externally. A plurality of conductive elements 27 such as solder balls or solder pins can also be formed on each of the conductive pillars 200 in each of the second holes 250b, in order to connect other electronic devices, such as a circuit board, a semiconductor chip or another package, externally.

In another embodiment, as shown in FIG. 4I′, if the above-described processes are performed according to the structure shown in FIG. 4G′, each of the first holes 250a exposed from the circuit layer 24 is formed in the first solder mask layer 25a, and each of the conductive elements 26 is formed on the exposed circuit layer 24, in order to connect other electronic devices 28. A second solder mask layer 25b′ is also can be formed on the second surface 23b of the dielectric layer 23, the heat sink 201 and each of the conductive pillars 200, and then a plurality of second holes 250b′ are formed in the second solder mask layer 25b′, allowing a part of each of the conductive pillars 200 to be exposed form each of the second holes 250b′, allowing the conductive elements 27 to be formed on each of the conductive pillars 200 in each of the second holes 250b′, so as to connect other electronic devices.

In another embodiment, as shown in FIG. 4F′, a built-up structure 29 may be alternatively formed on the first surface 23a of the dielectric layer 23 and the dielectric layer 24 first, and then the first solder mask layer 25a′ is formed on an outermost layer of the built-up structure 29, allowing a part of the outermost layer circuit of the built-up structure 29 to be exposed from the first holes 250a′, so as to form other conductive elements on the circuit in the first holes 250a′ in the subsequent process. The built-up structure 29 has at least one dielectric layer, a circuit formed on the dielectric layer, and a plurality of conductive blind vias formed in the dielectric layer and electrically connected to the circuit layer 24 and the circuit.

In another embodiment, another built-up structure may be further formed on the second surface 23b of the dielectric layer 23 (not shown in figures) after removing the carrier 20 (as shown in FIG. 4G or 4G′).

In the present invention, the chip 22 is mounted on the carrier 20, then the dielectric layer 23 covers the chip 22, and then the carrier 20 is removed, without using the glue film of the prior art. Therefore, the problems of the prior art that the encapsulant excessive glue and chip contamination are solved.

Moreover, in the present invention the chip 22 is mounted on the carrier 20 with the inactive surface 22b facing the carrier 20. Therefore, the extension/contraction problem due to the heating on the glue film does not happen, and the chip 22 will not be offset. Besides, the chip 22 does not generate any displacement, because the carrier 20, when heated, will not be softened during the formation of the dielectric layer 23. Accordingly, during the RDL process the circuit layer 24 may be in well contact with the electrode pads 220 of the chip 22, and the problem of invalid packages can be effectively avoid.

In the present invention, each of the conductive pillars 200 are formed on the carrier 20, such that the supporting force is increased and the whole structure does not suffer the warpage. Therefore, the problem of the prior art that the glue film is used as the only supporting force and thus the warpage is likely to happen is solved. Accordingly, the chip 22 does not offset. Therefore, during the RDL process the circuit layer 24 may be well in contact with the electrode pads 220, and the problem of invalid packages can be effectively avoid.

Through the design of the conductive pillars 200, when a stack process is performed conductive elements 27 such as solder balls may be used to connect another electronic device directly, without the need to penetrate the encapsulant to form the conductive vias. Therefore, the present invention has a simplified process, does not need of filling with the conductive material, and has a reduced fabrication time and cost.

The present invention further provides a package of embedded chip, including: a dielectric layer 23 having a first surface 23a and a second surface 23b opposing the first surface 23a; a plurality of conductive pillars 200 formed in the dielectric layer 23 and exposed from the second surfaces 23b of the dielectric layer 23; a chip 22 embedded in the dielectric layer 23; a circuit layer 24 formed on the first surface 23a of the dielectric layer 23; a plurality of conductive blind vias 240 formed in the dielectric layer 23; and a first solder mask layer 25a formed on the first surface 23a of the dielectric layer 23 and the circuit layer 24.

In an embodiment of the present invention, the conductive pillars 200 are made of copper.

The chip 22 has an active surface 22a and an inactive surface 22b opposing the active surface 22a. A plurality of electrode pads 220 are disposed on the active surface 22a.

The circuit layer 24 is electrically connected via the conductive blind vias 240 to the each of electrode pads 220 and each of the conductive pillars 200.

The first solder mask layer 25a has a plurality of first holes 250a, allowing a part of the circuit layer 24 to be exposed form each of the first holes 250a.

The package further comprises a plurality of conductive elements 26 formed on the circuit layer 24 in each of the first holes 250a.

The package further comprises a built-up structure 29 that is formed on the first surface 23a of the dielectric layer 23 and the circuit layer 24. The first solder mask layer 25a is formed on an outermost layer of the built-up structure 29.

In an embodiment, the inactive surface 22b of the chip 22 is exposed from the second surface 23b of the dielectric layer 23. The package further comprises a second solder mask layer 25b that is formed on the second surface 23b of the dielectric layer 23, the inactive surface 22b of the chip 22 and each of the conductive pillars 200, and the second solder mask layer 25b has a plurality of second holes 250b, allowing a part of the surfaces of each of the conductive pillars 200 to be exposed form the second holes 250b, allowing a plurality of conductive elements 27 to be formed on each of the conductive pillars 200 in the second holes 250b.

In another embodiment, the inactive surface 22b of the chip 22 has a heat sink 201. The package further comprises a second solder mask layer 25b formed on the second surface 23b of the dielectric layer 23, the heat sink 201 and each of the conductive pillars 200, and the second solder mask layer 25b has a plurality of second holes 250b, allowing a part of each of the conductive pillars 200 to be exposed form the second holes 250b, allowing the conductive elements 27 to be formed on each of the conductive pillars 200 in the second holes 250b.

In sum, the package of embedded chip and a method of fabricating the package of embedded chip of the present invention use the design of conductive pillars. Therefore, when a stack process is performed, solder balls may be used to connect another electronic devices directly, such that the process is simplified, and the fabrication time and cost are reduced. Moreover, the present invention uses a carrier to replace the glue film of the prior art, which solves the problems of encapsulant excessive glue and chip contamination.

Besides, through the carrier on which a chip may be mounted and the conductive pillars that may increase the whole supporting force, the warpage does not happen, and the chip does not suffer offset. Accordingly, during the RDL process the circuit layer is well in contact with the electrode pads, and the problem of invalid packages can be effectively avoid. Also, no metal or glue will be residual on the dielectric layer when the carrier is removed.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A package embedded with a chip, comprising:
a dielectric layer having a first surface and a second surface opposing the first surface;
a plurality of conductive pillars formed in the dielectric layer and exposed from the second surface of the dielectric layer;
the chip embedded in the dielectric layer and having an active surface and an inactive surface opposing the active surface, wherein a plurality of electrode pads are formed on the active surface;
a circuit layer formed on the first surface of the dielectric layer;
a plurality of conductive blind vias formed in the dielectric layer, allowing the circuit layer to be electrically connected via the conductive blind vias to each of the electrode pads and each of the conductive pillars; and
a first solder mask layer formed on the first surface of the dielectric layer and the circuit layer and having a plurality of first holes for exposing a part of the circuit layer from the first holes.

2. The package embedded with a chip of claim 1, wherein the conductive pillars are made of copper.

3. The package embedded with a chip of claim 1, wherein the inactive surface of the chip is exposed from the second surface of the dielectric layer.

4. The package embedded with a chip of claim 3, further comprising a second solder mask layer formed on the second surface of the dielectric layer, the inactive surface of the chip and each of the conductive pillars, wherein the second solder mask layer has a plurality of second holes for exposing a part of each of the conductive pillars form the second holes.

5. The package embedded with a chip of claim 1, further comprising a heat sink mounted on the inactive surface of the chip.

6. The package embedded with a chip of claim 5, further comprising a second solder mask layer formed on the second surface of the dielectric layer, the heat sink and each of the conductive pillars, wherein the second solder mask layer has a plurality of second holes for exposing a part of each of the conductive pillars from the second holes.

7. The package embedded with a chip of claim 1, further comprising a conductive element formed on the circuit layer in the first holes.

8. The package embedded with a chip of claim 1, further comprising a built-up structure formed on the first surface of the dielectric layer and the circuit layer, wherein the first solder mask layer is formed on an outermost layer of the built-up structure.

9. A method of fabricating a package embedded with chip, comprising:
forming a plurality of conductive pillars on a carrier, and defining a chip-mounted region on the carrier;
mounting on the chip-mounted region a chip having an active surface and an inactive surface opposing the active surface, with the inactive surface attached to the carrier, wherein a plurality of the electrode pads are formed on the active surface;
forming a dielectric layer on the carrier, each of the conductive pillars and the chip, wherein the chip is encapsulated by the dielectric layer and the dielectric layer has an exposed first surface and a second surface attached to the carrier;
forming a circuit layer on the exposed first surface of the dielectric layer, and forming a plurality of conductive blind vias in the dielectric layer, allowing the circuit layer to be electrically connected via the conductive blind vias to each of the electrode pads and each of the conductive pillars;
forming on the first surface of the dielectric layer and the circuit layer a first solder mask layer;
removing the carrier to expose the second surface of the dielectric layer and each of the conductive pillars; and
forming in the first solder mask layer a plurality of first holes for exposing a part of the circuit layer from the first holes.

10. The method of claim 9, wherein the carrier and the conductive pillars are made of copper.

11. The method of claim 9, further comprising coating the inactive surface of the chip with an adhesive layer, to allow the chip to be adhered in position on the carrier.

12. The method of claim 11, further comprising removing the adhesive layer after the carrier is removed for exposing the inactive surface of the chip.

13. The method of claim 9, wherein the carrier is removed by etching.

14. The method of claim 9, wherein the inactive surface of the chip is exposed from the second surface of the dielectric after the carrier is completely removed.

15. The method of claim 14, further comprising forming a second solder mask layer on the second surface of the dielectric layer, the inactive surface of the chip and each of the conductive pillars, wherein the second solder mask layer has a plurality of second holes for exposing a part of each of the conductive pillars from the second holes.

16. The method of claim 9, wherein a part of the carrier is removed, allowing the residual carrier on the inactive surface of the chip to act as a heat sink.

17. The method of claim 16, further comprising forming a second solder mask layer on the second surface of the dielectric layer, the heat sink and each of the conductive pillars, wherein the second solder mask layer has a plurality of second holes, for exposing a part of each of the conductive pillars from the second holes.

18. The method of claim 9, further comprising forming a conductive element on the circuit layer in the first holes.
